(19) United States
(12) Patent Application Publication
(10) Pub. No.: US 2021/0364194 A1
(43) Pub. Date: Nov. 25, 2021

(54) APPARATUS POWERED BY COMPRESSED FLUID

(71) Applicant: Cool Mine Pty Ltd, Brisbane (AU)

(72) Inventor: Mark Gleadhill, Main Beach (AU)

(21) Appl. No.: 17/250,949

(22) PCT Filed: Sep. 27, 2019
(86) PCT No.: PCT/AU2019/051048

§ 371 Date: Apr. 1, 2021

(30) Foreign Application Priority Data
Oct. 2, 2018 (AU) 2018903723

(51) Int. Cl. F25B 9/04; F25B 9/00; H01L 35/30; E21F 3/00; E21F 17/00; E21F 11/00

(52) U.S. Cl. CPC F25B 9/04; F25B 9/004; E21F 11/00; E21F 3/00; E21F 17/00; H01L 35/30

(57) ABSTRACT

An apparatus and method powered by compressed fluid, which preferably provides both air conditioning and power generation. The apparatus includes a fluid conduit of substantially elongate form (51), a helical accelerator (80), a substantially elongate distributor body (53) associated with said accelerator (80), wherein at least part of said distributor body (53) is positioned substantially coplanar to said fluid conduit (51), and a TEG device (55), positioned intermediate said fluid conduit (51) and said distributor body (53). In use, a compressed fluid (70) is supplied to an inlet (60) of said helical accelerator (80). The accelerator (80) causes the fluid (70) to form a vortex inside said distributor body (53) and thereby produce a hot fluid stream (71) and a cold fluid stream (72). The hot fluid stream (71) is directed to flow adjacent to a wall of said distributor (53) to thereby heat said distributor wall. The cold fluid stream (72) is at least partly directed to flow via said accelerator (80) to cool said fluid conduit (51), and, to cool a surrounding environment. A temperature differential is thereby created between said distributor wall and said conduit (51), to generate power in the TEG device (55).

### BACKGROUND OF THE INVENTION

The present invention relates to an apparatus which is driven by compressed gas. The present invention also relates to device which is adapted to generate an electric current. Furthermore, the present invention relates to a device which is adapted to provide air conditioning.

The present invention is particularly suitable for, but not limited to, use in mines or other remote locations where mains power supply is unavailable, inconvenient and/or undesirable.

### DESCRIPTION OF THE PRIOR ART

The Applicant has previously invented a device, which described in International Patent Publication No. WO/2017/205919, and which relates generally to separating a stream of compressed gas into separate hot and cold streams. A particular application for the device of WO/2017/205919 is to provide air-conditioning to an underground mine shaft which is powered by a compressed gas supply. This device has particularly useful application in situations where electrical power is not readily available and/or it may be dangerous to provide utilizing traditional type mains power supplies, such as in hazardous environmental conditions.

The invention described in WO/2017/205919, in one preferred implementation thereof, includes a tube like arrangement having a hot gas outlet at one end thereof and a cold gas outlet at a second end thereof. When a supply of compressed air is provided at an inlet of the device, it is fed into an accelerator so that a vortex in formed inside the tube. The vortex chamber thereby produces the hot and cold gas streams, which may then ultimately be used to ‘condition’ the inside of the mine or other environment, that is to, for example, cool down the temperature within mine, or, if desired in other embodiments, to heat up the environment.

The disclosures of the Applicants' earlier patent publication No WO/2017/205919 should be considered to be entirely incorporated within the present specification by this reference thereto.

However, any reference herein to known prior art does not, unless the contrary indication appears, constitute an admission that such prior art is commonly known by those skilled in the art to which the invention relates, at the priority date of this application.

### SUMMARY OF THE INVENTION

The present invention seeks to provide a thermoelectric generator (TEG) which is powered by a compressed fluid, such as compressed air or other gas.

Preferably the apparatus includes a vortex chamber adapted to receive the compressed gas and form separate hot and cold fluid streams.

Preferably the TEG device includes a solid state device adapted to produce an electrical current due to a temperature differential between the hot and cold fluid streams.

In a preferred form, the present invention provides an apparatus adapted to generate an electrical current including a vortex chamber powered by a compressed fluid to generate hot and cold fluid streams, and, a solid state TEG device adapted to produce an electrical current due to a temperature differential between said fluid streams.

In a further broad form the present invention provides an apparatus adapted to generate an electrical current including a compressed gas inlet, a vortex chamber connected to said compressed gas inlet, adapted to produce a hot gas stream and a cold gas stream, a first conduit connected to said chamber through which said hot gas stream is adapted to flow, a second conduit connected to said chamber through which said cold gas stream is adapted to flow and a TEG device positioned operatively between said first and second conduits, adapted to generate an electrical current from a temperature differential between said hot and cold gas streams flowing through said first and second conduits.

Preferably the apparatus is embodied wherein one of said conduits at least partially substantially surrounds the other of said conduits.

Preferably the apparatus is embodied wherein the TEG device includes a semiconductor device.

Also preferably the TEG device includes an electrical circuit adapted to power an electrical device.

Preferably, the gas is air.

In a further embodiment, the present invention provides an apparatus for generating an electrical current including a compressed gas inlet, a vortex chamber connected to said compressed gas inlet, a first conduit connected to an outlet of said chamber, a second conduit connected to an outlet of said chamber and a TEG device positioned intermediate said first and second conduits wherein, in use, a compressed gas is supplied at said inlet of said vortex chamber such that a hot gas stream and a cold gas stream are produced in said chamber and caused to flow through said first and second conduits, to thereby generate an electrical current in said TEG device as a result of a temperature differential between said gas streams flowing through said conduits.

Preferably the device of the invention includes a tube with a hot gas outlet at a first end and a cold gas outlet at a second end, an inlet in fluid communication with the tube, an accelerator associated with the tube and a thermoelectric generator (TEG) associated with the outlets wherein, the device is configured to accept a supply of compressed gas at the inlet, the accelerator causing the air to form a vortex inside the tube and the device producing a cold gas stream that exits from the cold gas outlet and a hot gas stream that exits from the hot gas outlet, and, the TEG is configured to generate an electric current due to a temperature differential between the hot and cold outlets.

Preferably the TEG apparatus includes a solid state device sandwiched between the hot and cold gas outlets and or the incoming compressed gas supply as disclosed in [0088].

A preferred embodiment of the invention is wherein the generator, apparatus or device is suitable for use in an underground mine.

Preferably the present invention also provides a method of generating an electrical current, including supplying a compressed gas to a vortex chamber in which the gas is separated into a hot gas stream and a cold gas stream directing the hot and cold gas streams into first and second conduits and, generating an electrical current in a TEG device positioned in thermal contact with each of said conduits when a temperature difference exists between said conduits.

Preferably the method of generating an electrical current is embodied wherein said TEG device is embodied as a solid state TEG device positioned intermediate said conduits.

Preferably the method of generating power uses a thermoelectric device powered by a compressed gas supply.

Preferably the method of generating power is embodied wherein the thermoelectric device is a solid state device.

In another embodiment, the present invention provides an apparatus for generating an electrical current including a TEG device positioned intermediate a pair of gas conduits, wherein, in use, hot and a cold gas streams flow in said conduits to thereby create a temperature differential across the TEG device such that an electrical current flows therein.

Another embodiment of the present invention seeks to provide an air conditioning and power generation apparatus, including: a fluid conduit of substantially elongate form; a helical accelerator; a substantially elongate distributor body associated with said accelerator, at least part of said distributor body being positioned substantially coplanar to said fluid conduit; a TEG device, positioned intermediate said fluid conduit and said distributor body; wherein, in use: a compressed fluid is supplied to an inlet of said helical accelerator; said accelerator causes the fluid to form a vortex inside said distributor body and thereby produce a hot fluid stream and a cold fluid stream; said hot fluid stream is directed to flow adjacent to a wall of said distributor to thereby heat said distributor wall; said cold fluid stream is at least partly directed to flow via said accelerator to cool said fluid conduit, and, to cool a surrounding environment; and, a temperature differential, created between said distributor wall and said conduit, causes power to be generated by said TEG device.

Preferably said fluid conduit includes: an inlet fluid conduit through which said compressed air is supplied to said helical accelerator; and, a cool air conduit through which at least part of said cold air stream is conveyed from said distributor body.

Preferably, said compressed air flows through said inlet fluid conduit towards said helical accelerator in a first direction, whilst said cold air stream conveyed from said distributor body via said cold air conduit flows in a second direction which is substantially opposed to said first direction, so as to counteract any uneven cooling within said cooling conduit.

Preferably said inlet fluid conduit is positioned proximal to said distributor body; and, said cool air conduit is surrounded by said inlet fluid conduit.

Preferably a hose conveys said cold air from said distributor to said cool air conduit.

Preferably the embodiment includes a plurality of fluid conduits; and; a plurality of TEG devices; each of said fluid conduits and said TEG devices being positioned so as to at least partly surround said distributor body.

Preferably said distributor body is in the form of a tube.

Preferably said distributor body includes a hot air control port at a first end thereof.

Preferably said hot air control port includes a valve device to regulate the egress of hot air from said distributor body, to thereby control the temperature of the fluids within said body.

Preferably said distributer includes a cold air outlet at a second end thereof.

Preferably said apparatus is embodied in modular form.

Preferably said cool air conduit includes a heat sink cold air return gallery.

### BRIEF DESCRIPTION OF THE DRAWINGS

The present invention will become more fully understood from the following description of preferred but non-limiting embodiments thereof, described in connection with the accompanying drawings, wherein:

FIG. 1 illustrates a schematic drawing of a TEG device of the present invention;

FIG. 2 illustrates a cross sectional view of a preferred arrangement of the present invention;

FIG. 3 illustrates a cross sectional view, of a preferred arrangement of the TEG's of FIG. 2, this drawing being orthogonal to the cross section of FIG. 2;

FIG. 4 illustrates an alternative arrangement of the present invention in cross sectional view, wherein three air streams are being put back into the containment surrounding the tubes/conduits;

FIG. 5 shows, in FIGS. 5a to 5d, various views of a distributor arrangement of the embodiment of FIG. 3;

FIG. 6 shows an alternatively preferred embodiment of the invention with one of the cold air streams being directed to an attached silencer;

FIG. 7 shows another preferred embodiment of the invention;

FIG. 8 shows an exploded perspective of the embodiment of FIG. 7;

FIG. 9 shows a cross-sectional perspective of the embodiment shown in FIG. 7;

FIG. 10 shows another cross-sectional view of the embodiment of FIG. 7, to indicate flow direction of gas during operation of the apparatus;

FIG. 11 shows a preferred embodiment of the helical accelerator;

FIG. 12 shows a cross-sectional side on view of the embodiment of FIG. 11;

FIG. 13 shows front on view of the embodiment of FIG. 11.

### DETAILED DESCRIPTION OF PREFERRED EMBODIMENTS

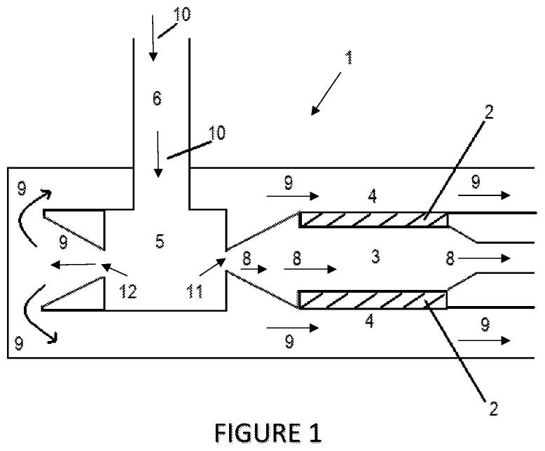

FIG. 1 shows a schematic diagram of a first embodiment of an apparatus of the present invention. The apparatus, generally designated by the numeral 1, includes a TEG device 2, typically embodied as a solid state or semiconductor device, which is at least partly sandwiched between a first fluid conduit 3 and a second fluid conduit 4. The first fluid conduit 3 may have a hot gas stream flowing through it, and the second fluid conduit 4 may have a cold gas stream flowing through it. As such, it will be understood that a temperature differential therefore exists between the first and second fluid conduits 3 and 4, respectively, such that a current is generated in the TEG device 2.

The operation of a TEG device, per se, will be understood by a person skilled in the art, and therefore will not be further described herein in detail. In essence, the TEG of the present invention is preferably embodied in the form of a relatively thin semiconductor, such that it may be readily attached, by an adhesive or other attachment means to the wall of the conduit. In other embodiments, the TEG device may be integrally formed as part of the wall of the fluid conduit(s). The solid state semiconductor device converts differences in temperature into electrical energy using the ‘seeback effect’. The TEG is a circuit containing thermoelectric materials joined at their ends, utilising an n-type, or negatively charged semiconductor material, and, a p-type, or positively charged semiconductor material. A direct current will flow in the circuit when there is a temperature difference between the ends of the materials. Generally, the magnitude of the current generated, is a function of, and generally directly proportional to the temperature difference.

The configuration of the conduits shown in FIG. 1 may be of any desired cross sectional shape, for example, circular, polygonal, etc., and, may, in one form, be embodied as a smaller conduit 3 inside a larger conduit 4. By forming the conduit(s) in a polygonal shape, a planar shaped TEG device may be readily attached to the straight edges of the polygonal conduit walls. Preferably, the TEG device may therefore be readily sandwiched between the conduits. It should however be appreciated that this is only one example of how the apparatus 1 may be embodied, and that other shapes and configurations allowing this function will be apparent to persons skilled in the art. For example the conduits may be side by side or in another spaced apart arrangement.

The TEG modules may be readily attached to the flat surfaces of a polygonal shaped conduit by means of a thermally conductive adhesive or glue or adhesive tape. The polygonal shape my for example be triangular in cross section, square, pentagonal, octagonal, or any other polygonal shape. The length and width of the flat surfaces of the polygonal tube or conduit may be selected such that the TEGs may be attached in multitude, as required to generate the power, voltage and/or current required.

The hot gas stream flowing through the inner conduit 3, is indicated in FIG. 1 by reference numeral 8, whilst the cold gas stream flowing through the outer conduit 4 is indicated by reference numeral 9.

The cold and hot and gas streams 8 and 9 are derived, in accordance with one preferred embodiment of the present invention, from a single source of compressed gas flowing in via the compressed gas inlet 6, as shown by reference numeral 10. The inlet 10 then supplies the compressed gas 6 into a compression chamber 5.

The chamber 5, is preferably embodied in the form of a vortex chamber. The vortex chamber creates the separated cold and hot gas streams 8 and 9 which then flow through the cold gas outlet 11 and the hot gas outlet 12. The operation of the vortex chamber is not describer further herein, as this will be understood by persons skilled in the art. A description of the operation of the vortex chamber 5 is however provided in the applicant's earlier patent specification, published as WO2017/205919, the specification of which should be considered to be fully incorporated herein by this reference thereto.

The apparatus of the present invention may be, in one version of the invention, utilised in combination with the invention of WO/2017/205919.

In another version of the invention, the apparatus of the present invention may be used separately from the invention of WO/2017/205919 and may be powered by compressed gas from an alternative source.

Variances may be made to the accelerators and the size and/or shape of the conduits/polygonal tubes to maximise the performance of the hot and cold gas stream ratios.

An effective and efficient temperature difference between the outer surface of the hot gas tube or tubes, of which the TEGs are attached, and the cold gas stream that passes over the opposite upward facing side of the TEG's, is required to ensure a continuous uninterruptable power supply failing loss of the compressed air supply or device failure. The containment that encompasses the hot tube or tubes allows unaffected guided passage of the cold and or compressed gas stream to pass over the upward facing (cold side) of the TEGs, effectively shielding the inner workings from the effects of the outer environment and potential mechanical harm. Such containment may have an Ingress Protection (IP) or Explosion Protection (Ex d) technique applied to its design.

As an additional method to enhance the cooling effect of the upward facing (cold side) of the TEGs, a finned heat sink made of an appropriate material, may be attached to assist with the raid dissipation of heat, transferred onto the TEGs from the hot tube surface, to the downward facing (hot side) of the TEGs. The heat sinks maybe attached to the upward facing (cold side) of each TEG, with the fins raising from the cold side face as someone skilled in the art would know. The heat sinks may be attached with a thermally conductive adhesive or tape.

In some adaptions of the device, one or more of the cold gas outlets are used to supply the cold air to a separate unrelated containment such as that of a personal workspace, concealed or confined space, refuge chamber and or any other such enclosure suitably sized to match the cooling output of the chosen cold gas tube. Such adaption of the one device allows for a multi-tiered use of a single device, including:
1. The temperature control of the major unrelated containment.
2. Pressurisation of the major unrelated containment for the purposes of creating a positive internal pressure to ensure no toxic or contaminated outside atmosphere enters the containment. Such uses are best explained as refuge chambers and COBS (change over bases) used in Underground Mining and tunneling operations, during times of escape, self-preservation and rescue.
3. The supply of electrical power to the unrelated containment for the use of but not limited to, low power devices such as transmitters, communication devices, LED lighting, gas & environmental monitoring, and battery charging/UPS (uninterruptable power supply) applications for such things as refuge chambers and COBs.
4. The redundancy of a compressed air driven air conditioning and electric power generation combined unit in the event that mains power is lost to such refuge chambers and COB's and or the battery power backup has depleted or failed.

The device with multiple hot and cold gas outlets, allows for the redundancy of multiple individual power supplies from the one device that can operate independent of each other offering reliability and built in redundancy of the device for the use in Underground Mining, in particular in refuge chambers and COBs, where survival in mine disaster conditions relies on such redundancies and reliabilities of survival equipment and apparatus.

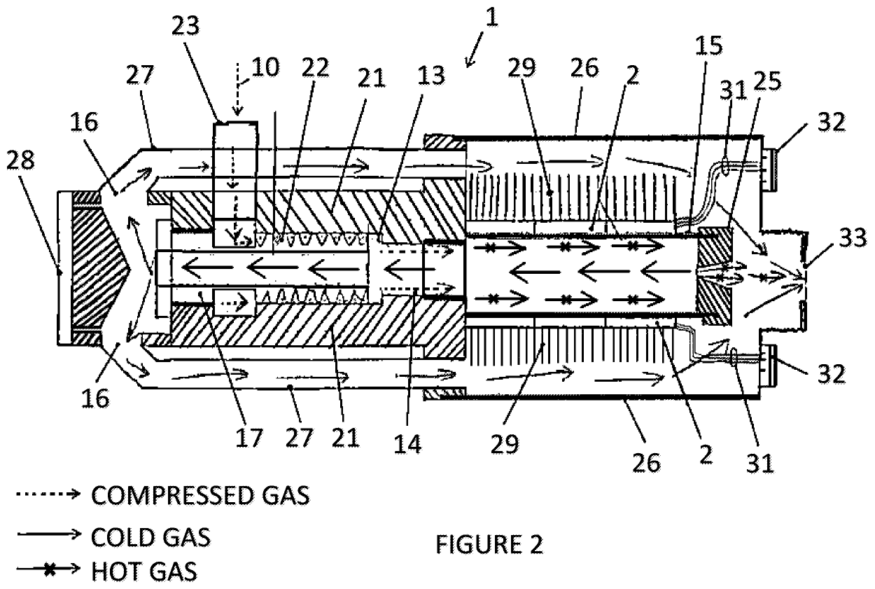

A more detailed description of the operation of the invention will now be described with reference to FIG. 2.

Compressed gas enters the inlet orifice 23, into the space of the main distributor body 21. The compressed gas is directed through the helical vanes of the helical accelerator 22 into the main distributor body spin chamber 13, wherein it gains rotational momentum to travel down the main distributor body delivery port 14 into the polygonal hot tube 5, which houses the outer attached thermoelectric generators (TEGs) 2.

The rotating gas stream travels to the end of the polygonal hot tube 15 where a controlled volume of the heated compressed gas may be released from the hot gas control release valve/orifice 25. This hot release of gas is mixed with the also venting cold gas stream via the threaded gas discharge connection 33, which may also connect to an external noise suppression device.

The hot gas that does not release from the hot gas release valve/orifice 25, returns down through the center of the outer rotating vortex of hot gas, in the same rotation and angular momentum as the outer rotating gas stream. The returning inner rotating gas stream gives up its energy in the form of heat to the outer rotating gas stream, where this heat is in fluid communication with the polygonal hot tube 15, effectively giving up its heat energy to the hot tube 15. This heat energy is further given up to the hot downward facing sides of the TEG's 2, which are in communication with the outer surface of the polygonal hot tube 15.

The inner rotating gas stream continues to return through the entire length of the polygonal hot tube 15, through the centre of the vertexing outer gas stream in the main distributor body delivery port 14 and spin chamber 13, entering the helical accelerator inner return port 16 as a super cooled singular gas stream.

The super cooled gas stream exits the helical accelerator inner return port 18, into the space created at the rear of the main distributor body 21 and the cold end directional access threaded plug 28. Cold gas is directed through multiple main distributor body cold gas exit ports 14, into the cold gas delivery tubes 27.

The cold gas streams travel through the cold gas delivery tubes 27, into the space created by the cold chamber containment shield 26. The cold gas passes through the space created by the cold chamber containment shield 26, passing over and through the fins and surfaces within of the heat sinks 29, that are in communication with the cold upward facing side of the TEG's 2. The cold gas stream removes transferred heat energy from the heat sinks and exits from the threaded gas discharge connection 33.

The differences in temperature between the hot and cold faces of the TEG's 2, converts into an electrical current that is transferred to the external electrical supply receptacle 32 via the TEG wiring looms 31

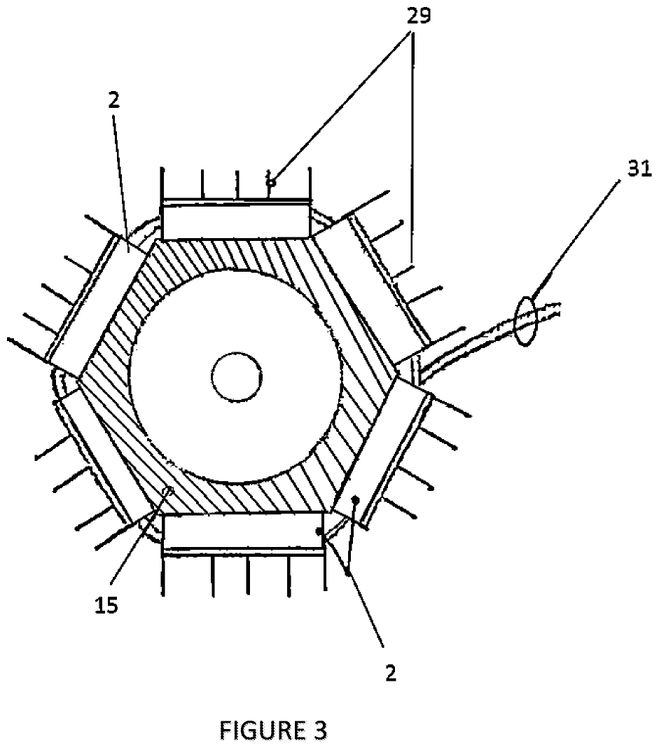

FIG. 3 shows a cross sectional view of a preferred TEG arrangement of FIG. 2. A first side of the TEGs 2 may preferably be placed on the exterior of conduit 15 through which cold gas flows. The TEG's 2 may be provided with heat sinks 29 attached to a second or opposed side thereof which protrude into the outer conduit through which the hot gas may flow. Due to the temperature differential between the sides of the TEG device 2, a current therefor flows, which may be tapped off via electrical wires 31.

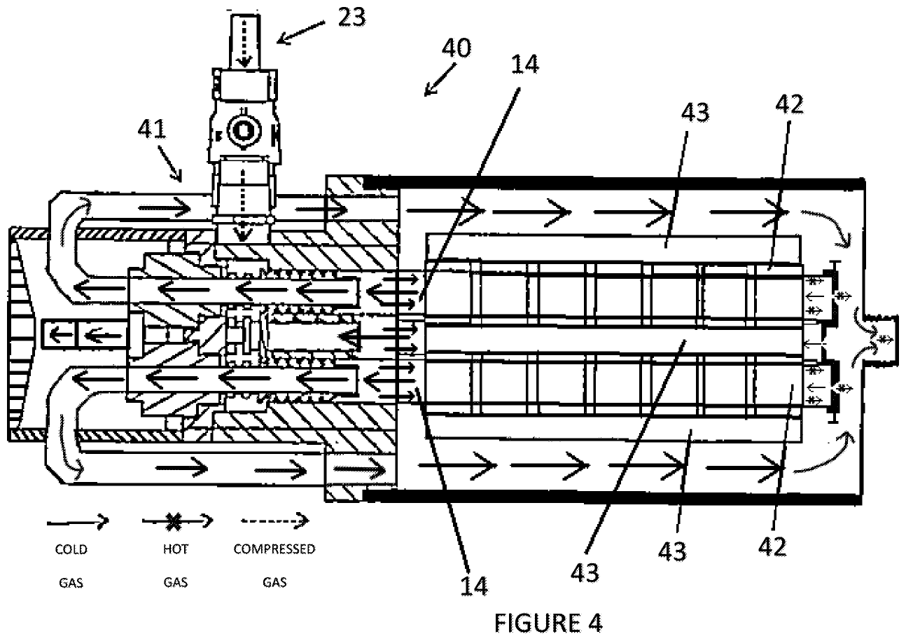

FIG. 4 shows another embodiment of the invention. In this embodiment, the apparatus incorporates an arrangement whereby multiple independent and differing power supplies may be generated by the apparatus. The embodiment of FIG. 4 illustrates the generation of two differing power supplies, however, as will be appreciated, the arrangement may be easily modified to generate any number of independent and differing power supplies.

As per the arrangement of FIG. 2, the multiple unit arrangement 40 of FIG. 4 also incorporates a compressed air inlet 23 for the supply of compressed air into the expansion chamber body 41, which includes three accelerator units 24, 25 and 26 to separate the compressed gas into different cold fluid flow paths, indicated by arrows 27, 28 and 29. All three airstreams are then conveyed back through the return cold gas output conduits surrounding the hot tubes to cool one side of the respective TEG devices 42. Finned heat sinks 43 and 44 may be provided on the TEG devices 42, to assist in providing improved thermal conductivity in the device.

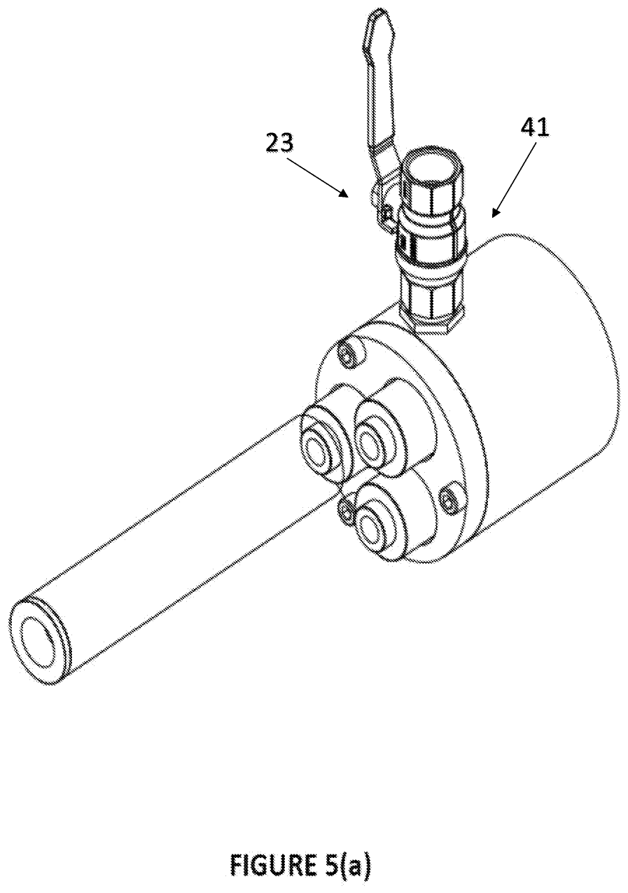

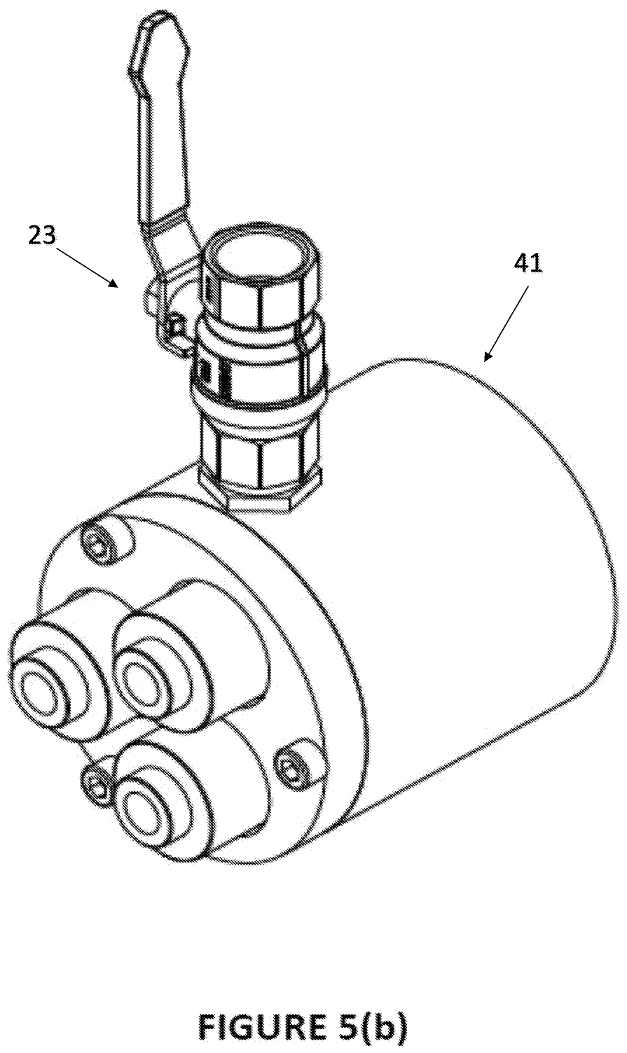

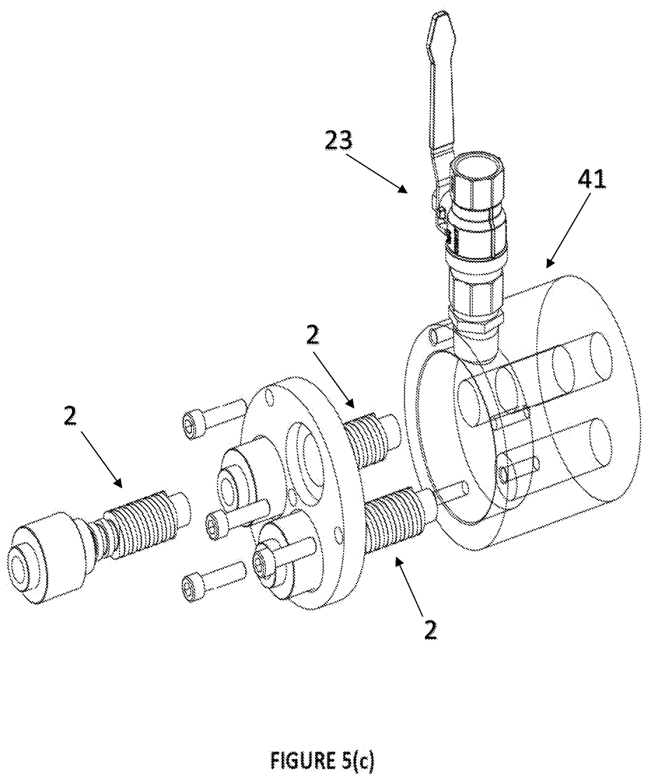

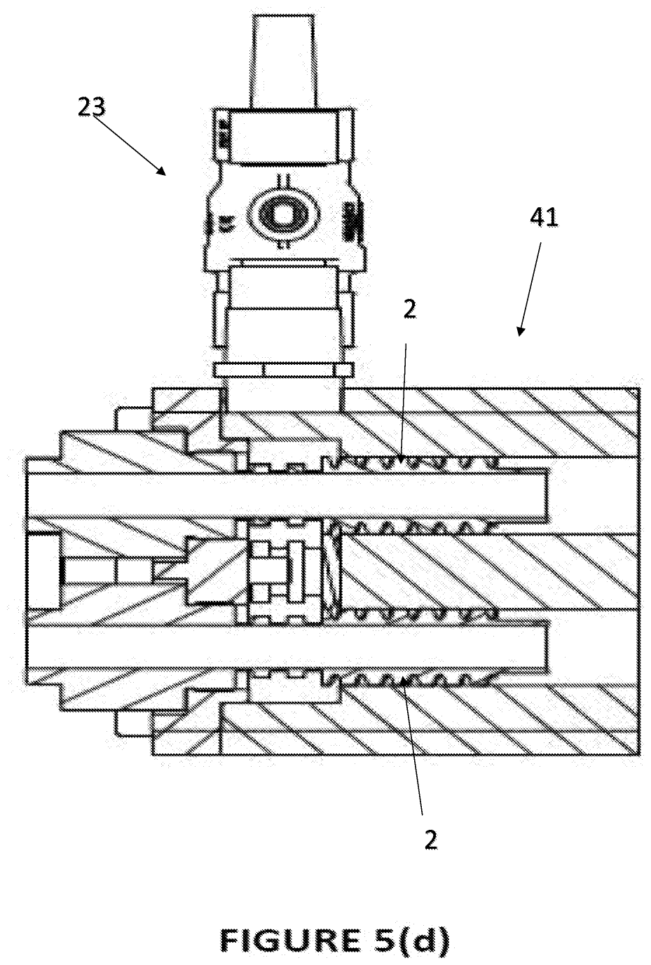

FIG. 5 shows, in FIGS. 5(a), 5(b), 5(c) and 5(d) thereof, isometric views of an embodiment of the multiple unit arrangement of FIG. 4, showing the multiple conduit arrangement.

The various FIG. 5 views show the multiple unit arrangement of FIG. 4, showing the multiple conduit arrangement, wherein compressed gas enters the inlet orifice 23, into the space of the main distributor body 41. The compressed gas is directed through the helical vanes of the three helical accelerators 2, 25 and 26 into the three main distributor body spin chambers, wherein it gains rotational momentum to travel down the three main distributor body delivery ports into the three polygonal hot tubes, which houses the outer attached TEG's.

The operation for the multi polygonal hot tube device is the same in principle to the above described single polygonal hot tube unit. There are no limits to the number of polygonal hot tubes, physical dimensions of the hot tubes and or number of sides determining the type of polygonal shape used, which ultimately determine the number of TEG's used and the resulting power rating of the device.

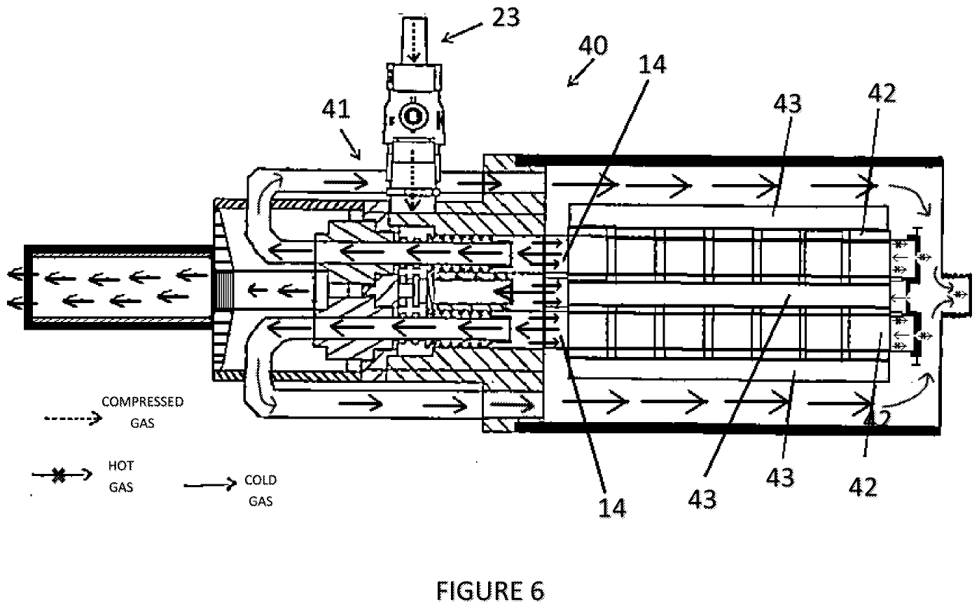

Like the single hot tube device, the cold end gas can be directed back to the cold gas containment shield void in its entirety with the number of cold gas returns employed as per FIG. 4, or, it can be divided, as per FIG. 6, to allow an effective portion of the cold gas returning to cool the TEG's in the void and the remaining cold gas outlets used to air condition and or pressurise a separate containment at high volume such as a refuge chamber and or COB's used in underground mining.

As seen in FIG. 5, a distributor main body with three helical accelerators of with the compressed has enters via a top inlet, is set into vortex motion upon exiting the helical groove of the accelerator. Not pictured above but extending from the ports on the RHS of the distributor main body may be the three hot tubes and from the LHS the returning cold has stream exits. For the sake of FIG. 5(a) and FIG. 6, one of the accelerators exiting cold air on the LHS will have a noise silencer extending to deliver cold air to the refuge chamber, and the other two will have their cold gas stream delivered to the LHS that would have an encompassing containment surrounding the three hot tubes, not unlike the heat shield in the Applicant's aforementioned previous patent specification. All three hot tubes may be polygonal in shape to each house several TEGs connected in a compliment of series and parallel configurations to achieve the end desired power output required.

A single tube device used for the sole purpose of supplying electrical power to a fixed device, such as, but not limited to, low power devices such as transmitters, communication devices, LED lighting, gas & environmental monitoring, and battery charging/UPS (uninterruptable power supply) applications, in particular for underground mining areas where the powering of such low power devices is often required and or mandated in remote areas of the mine, but requires the infrastructure and resources of a much larger installation to energise these low power fixed devices. In many such cases as this, in particular in underground coal mining, it may cost in excess of $1M of equipment, electrical reticulation and installation resources, to supply power to a device that is of insignificant power consumption, but a legislated or best practice requirement.

To enable this device to be able to use in hazardous environments such as underground coal mines and petrochemical/gas industries, in one form it would be designed with the required explosion protection technique method of energy limitation (Ex i) for intrinsic safety with the appropriate legislated ingress protection (IP) technique to support it. This may vary from country to country and will be sought through the IEC Ex System being the International Electrotechnical Commission System for Certification to Standards Relating to Equipment for Use in Explosive Atmospheres. Devices that do not carry the explosion protection techniques will have the required legislated Ingress Protection (IP) ratings and meet the requirements for electrical overload, earth leakage (if applicable) and short circuit protection as governed in the territory used and any other required minimum specification for electrical apparatus and power generation equipment.

In another form, the device may choose not to have any cooling air used as the medium to cool the upward face (cold side) side of the TEGs within the encompassing containment but use flowing water as the medium in a series of heat exchange tubes in contact with the TEG faces but not fluid communication.

The example diagrams depict both scenarios with all 3 cold gas returns being used to cool the TEG's and another form showing 2 of the 3 cold gas returns being directed back to the void that allows the cooling of the TEG's and the third cold gas return being directed out through the cold end directional access threaded plug with threaded port for cold gas extension silencer and exiting through the cold gas extension silencer.

It should be now be understood that the multiple hot tube device allows for varying helical accelerator CFM ratings to be employed to best suit the end user application requirements of both electrical energy requirement and volume/temperature of the cold gas required to effectively cool and pressurise a refuge chamber and or COB.

By varying the temperature differences across the TEG devices and/or by varying the TEG devices themselves, different amounts of power or current may be generated in the TEG devices. This allows the generation of different power supplies depending on the power requirements of different electrical devices which may be fed powered from the apparatus of the present invention.

Whilst the embodiments of FIGS. 2, 4 and 6 show an apparatus which provides both air conditioning and power generation, it will be appreciated that the apparatus may be alternatively embodied in a form whereby the hot and cold fluid supplies may be provided remote of the TEG device, that is, without the incorporation of an integrally formed vortex chamber device. That is, the hot and cold fluids may be provided from separate vortex chamber device, of from a remote location via appropriate conduits.

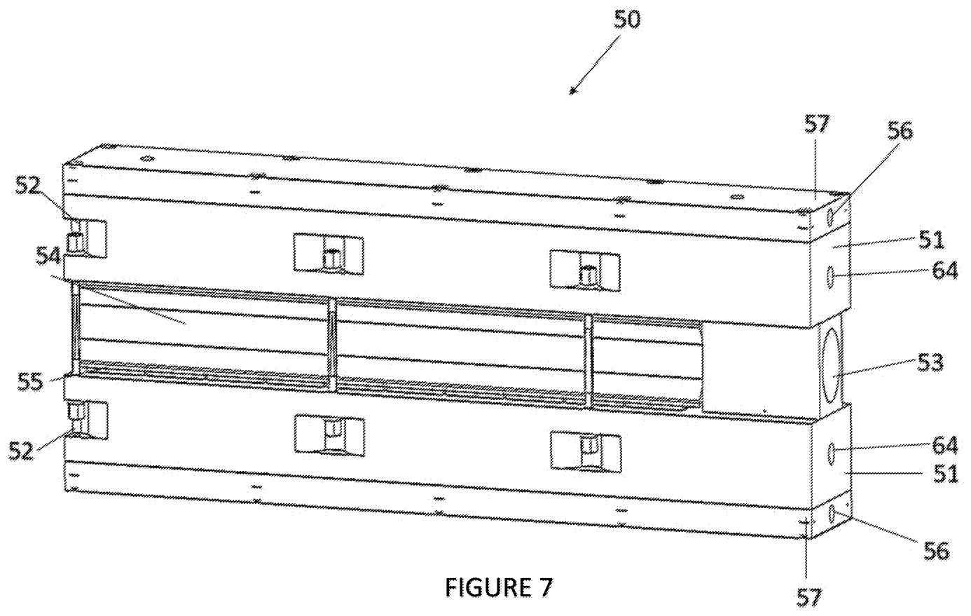

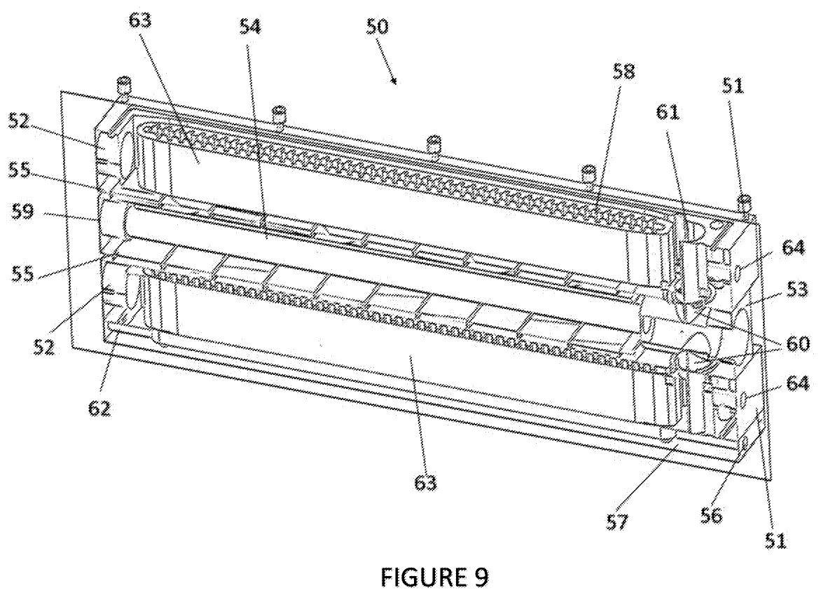

An alternative but also preferred embodiment of the present invention is shown in FIGS. 7 to 10.

The air conditioning and power generation apparatus 50 shown in FIGS. 7 to 9 is embodied in a modular form. The modular form of the present invention facilitates for ease of manufacture and assembly of the apparatus, the various components being able to be connected together, for example, by screw connections.

The apparatus 50 includes a distributor body 53 which is substantially elongate in shape. Disposed either side of the distributor body 53, is a fluid conduit 51. Each fluid conduit 51 is also substantially elongate in shape and includes an outer surface which is substantially coplanar to an outside surface of the distributor body 53.

A plurality of thermos-electric generator (TEG) device arrays 55 are sandwiched between the outer surface of the distributor body 53 and the outer surface of the fluid conduit 51. At least part of the distributor body 53 is coplanar to the fluid conduit 51.

The main distributor body 53 includes a helical accelerator 80 therein, which operates as described hereinbefore with reference to the previous embodiments.

In use, a compressed fluid, typically compressed air is supplied to an inlet 60 of the helical accelerator 80.

The accelerator 80 causes the air or other fluid to form a vortex inside the accelerator 80 said distributor body 53 and thereby produce a hot fluid stream and a cold fluid stream.

The hot fluid stream, as indicated by arrow 71, is directed to flow adjacent to a wall of the distributor 53 to thereby heat the distributor wall.

The cold fluid stream, as indicated by arrow 72, is at least partly directed to flow via said accelerator to cool said fluid conduit, and, to cool a surrounding environment.

A temperature differential, created between said distributor wall and said conduit, causes power to be generated by said TEG device.

The fluid conduit 63, includes an inlet fluid conduit 52 through which said compressed air 70 is supplied to said helical accelerator 53.

The fluid conduit 63 also includes a cool air conduit 57 through which at least part of said cold air stream is conveyed from said distributor body 53.

As shown, the inlet fluid conduit 52 is positioned proximal to said distributor body 53, and, the cool air conduit 57 surrounds the inlet fluid conduit 53.

A hose or other conduit preferably conveys said cold air from said distributor 53 to said cool air conduit 57.

As such, in this configuration, the incoming compressed gas 70 is not only cooling but also using heat energy it is drawing from the heat sink 51 as a means to increase the internal temperatures for efficiency.

Additionally, the compressed inlet gas 70 and cold air return gases 72, being segregated, and being supplied from opposing ends, effectively acts to negate any issues with uneven cooling.

Another effect of this segregation of air cooling and the provision of heat sink blocks is that they offer separation of the TEGs from the working gases whilst being still part of the same unit.

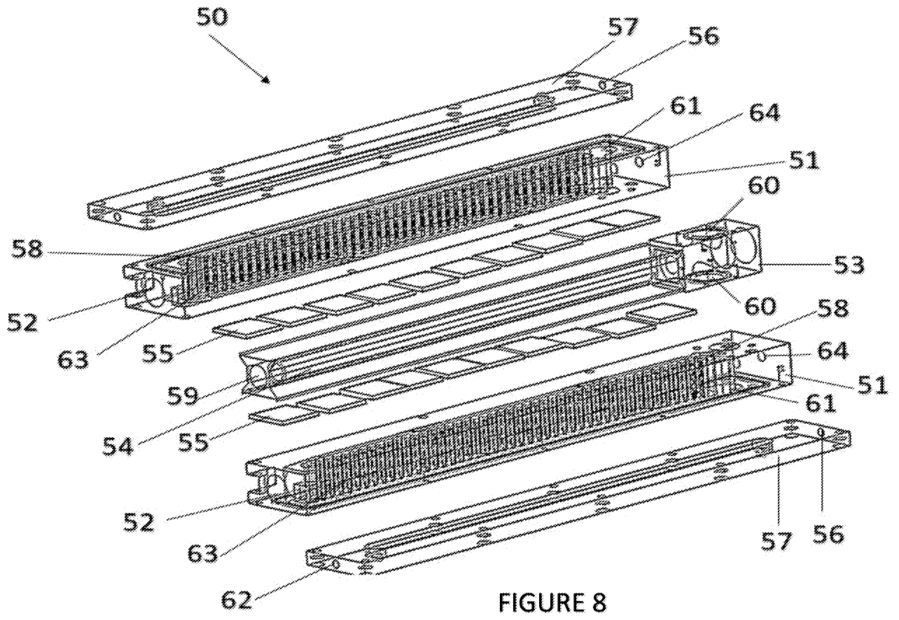

The illustrated embodiment of FIGS. 8 to 10, show a pair of fluid conduits 63, one on either side of the distributor body 53. It will however be appreciated by persons skilled in the art, that different geometric configurations of the illustrated apparatus are possible, whereby a plurality of fluid conduits 52 and a plurality of TEG devices 55 may be positions to at least partly surround the distributor body 53.

In the illustrated embodiment, the distributor body 53 is also described as being in the form of a tube. It will become apparent that other geometric shapes are possible to achieve the functional operation of the invention, and as such the present invention should not be construed as being limited to this tubular shape.

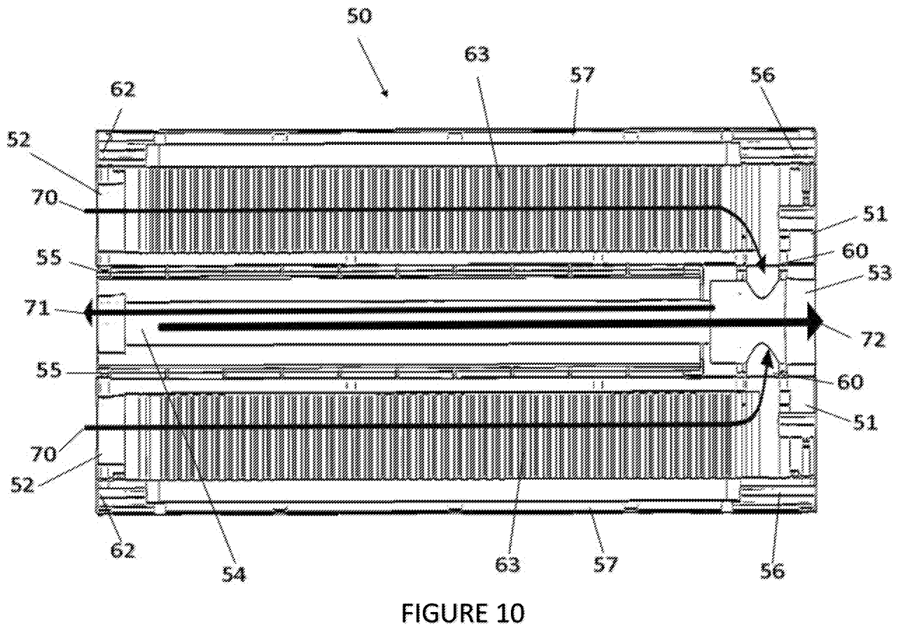

As shown in FIG. 10, the distributor body 53 includes a hot air control port at a first end thereof. This allows the temperature of the fluid in the distributor to be controlled by the controlled expelling of the hot gases from within the distributor body. This may be embodied by having a valve device to regulate the egress of hot air from said distributor body, to thereby control the temperature of the fluids within said body

FIG. 8 shows an exploded perspective ghost view, to illustrate some of the internal components of this embodiment of the invention. In particular, FIG. 8 shows the internal gallery peripheries 61 and sealed heat sink cold air return gallery 58 of the heat sink air delivery 51, the hot tube 54 and hot tube control port 59 of the main distributor body 53, and, the distributor entry ports 60 that allow a fluid connection between the main distributor body 53 and the heat sink air delivery 51.

As seen in FIG. 10, regulated compressed air enters the unit via the upper and lower heat sink air delivery 51 and cold air return block 57 assemblies at the compressed air inlet port 52. The incoming compressed air 70 passes around the internal gallery peripheries 61 of heat sink air delivery 51 and cold air return block 51, whereby it enters the main distributor body 53, via the upper and lower distributor entry ports 60 on the heat sink air delivery and cold air return block 51 and the main distributor body 53.

Upon the compressed air 70 entering the main distributor body 53 of, the compressed air 70 is passed around the peripheral helical groove of the helical accelerator 80. Compressed air 71 leaves the peripheral helical groove and accelerates down the hot tube 54 where the generated heat created by the vortex phenomenon is transferred through the material of the hot tube 54 onto the flat surfaces housing the upper and lower TEG array's 55.

A small amount of hot air 71 is regulated through the hot tube control port 59 allowing for the required hot and cold temperature control of the internal gasses. The larger portion of the compressed air 71 that is not released from the hot tube control port 59, then travels back through the center of the internal hot air vortex whereby the returning air 72 is made cold via the following process. Dynamic energy is given up as heat from the inner low pressure vortex to the outer hot air vortex, due to the inner vortex having a loss in angular momentum. Otherwise stated, the inner vortex spins at the same rotational speed as the outer vortex rather than an expected increase in speed of the inner vortex as dictated by the principle of conservation of angular momentum. This shift in angular momentum creates a “drag” on the inner vortex, slowing it and creating heat energy that it gives off to the outer vortex, effectively cooling the inner vortex.

Cold air 72 passes back through a center orifice through the helical accelerator, whereby it is carried via copper connection hoses (not pictured) to the cold air supply ports 56 on the upper and lower cold air return block 57, that is mounted onto the heat sink air delivery 51 and cold air return block 57. Cold air 72 is carried into the sealed heat sink cold air return gallery 58 of the heat sink air delivery 51 and cold air return block 57, whereby it is vented via a control outlet port 62 located at the opposing end of the cold air return block 57.

The TEG arrays 55 are sandwiched between the upper and lower heat sink air delivery 51 and cold air return block 57 assembly and the upper and lower housing planes of the hot tube 54 of the main distributor body 53.

This arrangement of the TEG arrays 55 results in several advantages.

Firstly the TEG's are not exposed to any compressed air for the operation allowing for intrinsic safety certification that the electrical components are not in direct communication of any working fluid and their contaminants. Also as the TEG's act as a heat pump, the best extraction of the available heat energy from the vortex phenomenon can be extracted.

Yet another advantage is that it allows the entire invention 50 to be modular. This allows for the addition of extension blocks of the hot tube 54 for greater capacity with no increased compressed air usage. Also there is no thermal losses with the returning cold air 72 passing directly through the hot tube 54 space. All the TEG devices are completely segregated and isolated from any interaction between the hot 71 and cold air 72 streams. Finally is allows the use of a single vortex unit with dual independently controlled and balanced TEG Arrays 55.

Furthermore the two piece heat sink air delivery 51 and cold air return block 57 assembly offers several novel benefits that overcome issues with effective cooling to generate the temperature separation required to produce adequate electrical power. This is achieved by a novel use of not only the cold air 72 return, but also the incoming stable compressed air 70 temperature. The stable repeatable temperature of the incoming compressed air 70 is used as a cooling medium for the heat sink assembly 63 mounted on the upper and lower TEG Array 55. The compressed air 70 is purposely delivered from the far end of the TEG array 55 from the distributor 53. This is to not only cool the heat sink 63 starting from the opposite end to the returning cold air 72, avoiding uneven cooling across the TEG array 55, but also purposeful in supplying the vortex phenomenon with heated compressed air 70 achieved through the cooling of the heat sink assembly 63. The TEG's work best with increased hot temperatures to achieve the differential temperatures, as opposed to increased cooling, to generate a greater temperature differential (Delta T).

The higher the hot tube 54 temperature gets, the greater the temperature communicated through to the heat sink 63 assembly from the heat pump action of the TEG array 55. As the incoming compressed air 70 is a stable temperature, its cooling ability will take hotter air into the distributor 53 and so it will increase to a higher value linear to time until the maximum cooling ability of the stable temperature compressed air 70 is met giving the maximum available Delta T by scavenging and recycling heat that would otherwise only have a single use.

The present invention also offers a method of self-contained energy harvesting for unit efficiency.

Yet another advantage of the present invention is due to the returning cold air 72 through the cold air return block 57 into the sealed and segregated heat sink cold air return gallery 58 of the heat sink air delivery 51, starts at the opposite end of the incoming compressed air 70 cooling circuit balancing the thermal differences between the TEG arrays 55 at either end eliminating temperature imbalance and hence imbalance in electrical energy generation between the TEG's.

Also the control ports 59, 62 and 64 located in the heat sink air delivery 51, the main distributor body 53 and the cold air return block 57 respectively, allow for the correct balancing and control of incoming and outgoing airflows to maximise the benefit of the compressed air-cooling circuit as described above.

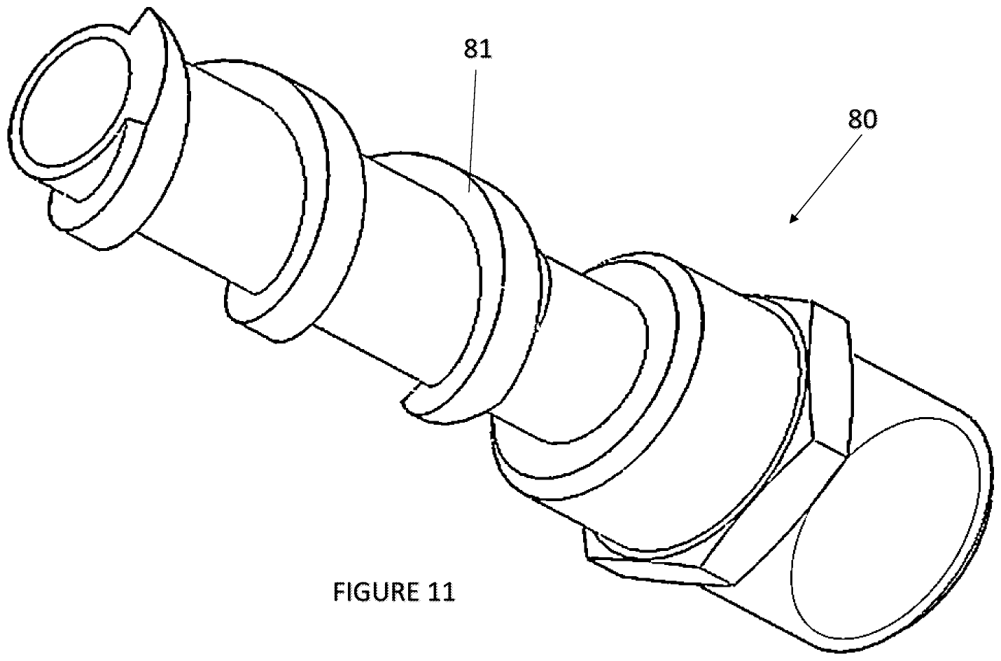

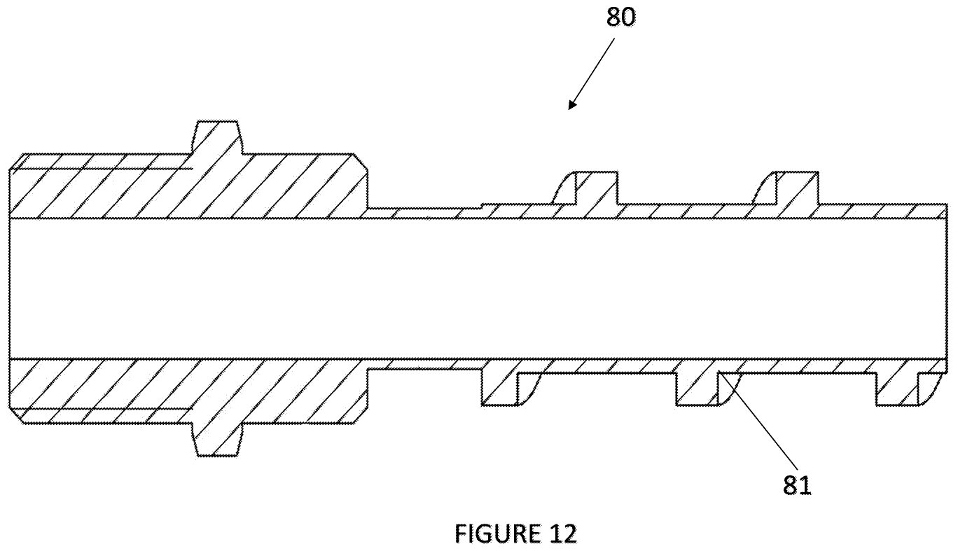

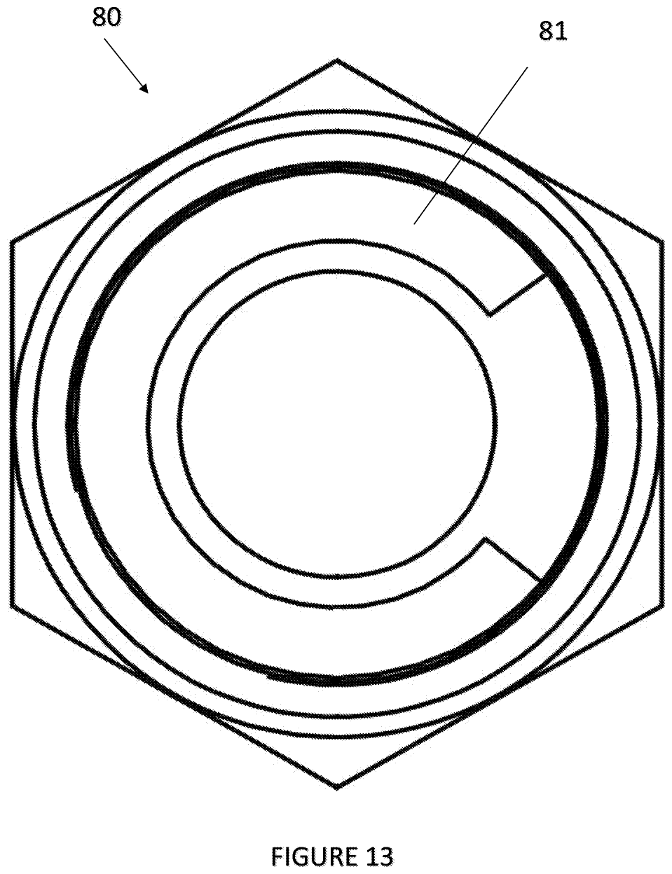

FIGS. 11 to 13 show a preferred embodiment of the helical accelerator 80. The helical accelerator 80 is specifically sized to fit snugly into the main distributor body 53. It can be seen that the helical accelerator 80 includes peripheral helical grooves 81 at one end and a bored out tunnel through the center. These peripheral helical grooves 81 assist in creating a vortex of compressed air 70 and the bored out tunnel allows returning cold air 72 to pass through it and be distributed to the cold air return block 57.

As it is important that the present invention 50 is capable of being used in extreme environments, such as mine sites, the present invention may be constructed as a uninterruptible power supply (UPS) that will have a standard version that is compliant to the required ingress protection standards and an intrinsically safe Ex ia Group 1 UPS for explosive atmospheres.

Currently Intrinsically Safe Ex ia Group 1 UPS's used in explosive atmospheres, only have their output as certified as intrinsically safe, due to their input supply to the UPS being Ex d, using the explosion protection technique for its input compliance. Unfortunately, Ex d explosion protection technique is not allowed to be used in a Group 1 hazardous area, Intrinsically Safe is the only technique allowed in the Zone 1 areas. Employing the cooling methods described above allows the full compliance of the present invention product to meet certification requirements with regards to the separation and isolation of the electrical equipment from any direct contact with the compressed air supply.

It will be obvious to those skilled in the art that the present inventions novelty will also extend to it being the only power supply that can be certified for installation within zone 1 areas in its entirety, the benefits of which are enormous. Currently the UPS's have to be installed outside of the zone 1 areas and the I.S. output supply then run into the zone to be used as required.

It will be appreciated that the present invention therefore provides a system of cooling and increased internal heating, which is substantially more efficient than traditional configurations. The apparatus of the present invention therefore enables the required power to be extracted from the apparatus, whilst providing an apparatus which is an intrinsically safe UPS that can support its load, charge the batteries within, and also preferably have redundant to burn off.

The arrangement of the present invention therefore enables the physical size of the apparatus to be reduced by approximately half those of traditional apparatus, as well as reducing the required air consumption by up to 60% by scavenging the heat with the incoming air supply.

Whilst the terms ‘hot’ and ‘cold’ are used within the specification, for example in relation to describing the gas streams flowing in conduits 3 and 4, it should be noted that these are merely used as relative terms, to indicate that the gas streams are of different temperatures, which are the requirement for operation of the TEG device.

In preferred arrangement of the invention compressed gas such as compressed air or compressed oxygen or other forms of compressed gases may be used. In other arrangements, water or other liquids may be used alternatively or additionally in the conduits.

Whilst the aforementioned embodiments describe the invention utilising hot and cold gases, it will be appreciated that the term fluid may be alternatively used, to include both gas and liquid. It should be understood that a person skilled in the art will know when it is appropriate to interchangeably use the terms liquid, gas and fluid, and other such terms which have similar meaning.

It will be understood that the present invention has particular application in environments such as in underground mines, where it may be dangerous and/or inconvenient to use a conventional source of mains power. Mines, for example are prone to have dangerous levels of hazardous gas therein, whereby the provision of mains electrical power may readily lead to an explosion therein, without the required expensive explosion protection techniques being employed, to the sizable reticulation network and resources required to power these low power remote devices. It will therefore be appreciated that the use of compressed gas to thereby provide a source of electrical power through a suitably employed explosion protection technique such as energy limitation (Intrinsic Safety Ex i), but without the need to feed a mains type power supply into the mine area will substantially minimise such dangerous risk.

The device of the present invention will also be appreciated to have particular application to refuge chambers and/or a change-over-base (COB) in mine shafts, which may be prone to lose a conventional mains type power supply in a hazardous situation. A refuge chamber in a mine shaft is to provide mine workers with a place of safety to gather in the event of an emergency situation, whilst they may typically await rescue or recovery operations. A COB is generally an enclosure built into the mining roadway for housing self-escape breathing apparatus and the like as a stop off point to replace or charge personal self-breathing apparatus and the like.

The provision of the compressed gas source to thereby provide a safer electrical power supply overcomes issues whereby the mains power supply may be lost in an emergency situation, particularly in these environments. The TEG device of the present invention may be used to power vital communications equipment, etc. in such an emergency situation, whilst when used in conjunction with the device of the applicants earlier invention, also supplies ‘conditioned’ air, i.e. either heated or cooled air, to either heat or cool the environment, as desired.

The present invention has been herein described with reference to specific examples. It should be understood that numerous variations and modifications will become apparent to persons skilled in the art from reading this specification. All such variations and modifications should be considered to fall within the spirit and scope of the invention as hereinbefore described and as hereinafter claimed.

1. An air conditioning and power generation apparatus, comprising:
an inlet fluid conduit of substantially elongate form through which compressed fluid is supplied in a first direction;
a helical accelerator;
a substantially elongate distributor body associated with said accelerator, at least part of said distributor body being positioned substantially coplanar to said inlet fluid conduit;
a TEG device, positioned intermediate said inlet fluid conduit and said distributor body; and,
an outer fluid conduit of substantially elongate form at least partially surrounding said inlet fluid conduit;
wherein, in use:
a compressed fluid is supplied via said inlet fluid conduit to an inlet of said helical accelerator;
said accelerator causes the fluid to form a vortex inside said distributor body and thereby produce a hot fluid stream and a cold fluid stream;
said hot fluid stream is directed to flow adjacent to a wall of said distributor to thereby heat said distributor wall;
said cold fluid stream is at least partly directed to flow to said outer fluid conduit in a second direction which is opposed to said first direction so as to counteract any uneven cooling within said inlet fluid conduit, and, to cool a surrounding environment; and,
a temperature differential, created between said distributor wall and said conduits, causes power to be generated by said TEG device.

2. An apparatus as claimed in claim 1, wherein:
a hose conveys said cold air from said distributor to said outer fluid conduit.

3. An apparatus as claimed in claim 1, including:
a plurality of fluid conduits; and;
a plurality of TEG devices;
each of said fluid conduits and said TEG devices being positioned so as to at least partly surround said distributor body.

4. An apparatus as claimed in claim 1, wherein:
said distributor body is in the form of a tube.

5. An apparatus as claimed in claim 1, wherein:
said distributor body includes a hot air control port at a first end thereof.

6. An apparatus as claimed in claim 1, wherein said hot air control port includes a valve device to regulate the egress of hot air from said distributor body, to thereby control the temperature of the fluids within said body.

7. An apparatus as claimed in claim 1, wherein:
said distributer includes a cold air outlet at a second end thereof.

8. An apparatus as claimed in claim 1, wherein:
said apparatus is embodied in modular form.

9. An apparatus as claimed in claim 1, wherein said outer fluid conduit includes a heat sink cold air return gallery.

10. A thermoelectric power generation (TEG) apparatus powered by compressed fluid, comprising:
an inlet fluid conduit of substantially elongate form through which said compressed fluid is supplied in a first direction;
a helical accelerator;
a substantially elongate distributor body associated with said accelerator, at least part of said distributor body being positioned substantially coplanar to said inlet fluid conduit;
a TEG device, positioned intermediate said inlet fluid conduit and said distributor body; and,
an outer fluid conduit of substantially elongate form at least partially surrounding said inlet fluid conduit;
wherein, in use:
a compressed fluid is supplied via said inlet fluid conduit to an inlet of said helical accelerator;
said accelerator causes the fluid to form a vortex inside said distributor body and thereby produce a hot fluid stream and a cold fluid stream;
said hot fluid stream is directed to flow adjacent to a wall of said distributor to thereby heat said distributor wall;
said cold fluid stream is at least partly directed to flow to said outer fluid conduit in a second direction which is opposed to said first direction so as to counteract any uneven cooling within said inlet fluid conduit; and,
a temperature differential, created between said distributor wall and said conduits, causes power to be generated by said TEG device.

11. An apparatus as claimed in claim 10, wherein:
a hose conveys said cold air from said distributor to said outer fluid conduit.

12. An apparatus as claimed in claim 10, including:
a plurality of fluid conduits; and;
a plurality of TEG devices;
each of said fluid conduits and said TEG devices being positioned so as to at least partly surround said distributor body.

13. An apparatus as claimed in claim 10, wherein:
said distributor body is in the form of a tube.

14. An apparatus as claimed in claim 10, wherein:
said distributor body includes a hot air control port at a first end thereof.

15. An apparatus as claimed in claim 10, wherein said hot air control port includes a valve device to regulate the egress of hot air from said distributor body, to thereby control the temperature of the fluids within said body.

16. An apparatus as claimed in claim 10, wherein:
said distributer includes a cold air outlet at a second end thereof.

17. An apparatus as claimed in claim 10, wherein:
said apparatus is embodied in modular form.

18. An apparatus as claimed in claim 10, wherein said outer fluid conduit includes a heat sink cold air return gallery.

19. An apparatus as claimed in claim 10, wherein said TEG devices are not in direct communication with said hot or cold fluid streams.
